(19) United States
(12) Patent Application Publication
(10) Pub. No.: US 2025/0369424 A1
(43) Pub. Date: Dec. 4, 2025

(54) EXPLAINABLE METHOD FOR MONITORING STATE OF GENERATOR OF WIND TURBINE GENERATOR SYSTEM ON BASIS OF SPATIO-TEMPORAL GRAPH

(71) Applicant: ZHEJIANG UNIVERSITY OF TECHNOLOGY, Zhejiang (CN)

(72) Inventors: Xiaohang JIN, Zhejiang (CN); Shengye LV, Zhejiang (CN)

(73) Assignee: ZHEJIANG UNIVERSITY OF TECHNOLOGY, Zhejiang (CN)

(21) Appl. No.: 18/764,053

(22) Filed: Jul. 3, 2024

(30) Foreign Application Priority Data
May 29, 2024 (CN) 202410680103.0

(51) Int. Cl. F03D 17/00; G01R 31/34

(52) U.S. Cl. CPC F03D 17/036; G01R 31/343; F05B 2260/83

(57) ABSTRACT

Disclosed is an explainable method for monitoring a state of a generator of a wind turbine generator system on the basis of a spatio-temporal graph. The method includes: S1: acquiring data collected by a supervisory control and data acquisition (SCADA) system; S2: carrying out data understanding on the SCADA data, selecting features associated with the generator, and carrying out data preparation on the selected feature data, and obtaining valid data; S3: embedding the SCADA data, and forming a directed spatio-temporal graph data sequence; and S4: carrying out modeling of a normal behavior model of the generator on the constructed directed spatio-temporal graph data sequence, computing a full-graph-level residual and a node-level residual, computing a residual through an exponentially weighted moving average (EWMA) control chart method, carrying out full-graph-level state monitoring on the generator, forming a fault information transmission chain relation, and enhancing explainability and robustness of a monitoring result.

### CROSS-REFERENCE TO RELATED APPLICATION

This application claims the priority benefit of China application serial no. 202410680103.0, filed on May 29, 2024. The entirety of the above-mentioned patent application is hereby incorporated by reference herein and made a part of this specification.

### TECHNICAL FIELD

The present disclosure belongs to the technical field of intelligent state monitoring of wind turbine generators, and particularly relates to an explainable method for monitoring a state of a generator of a wind turbine generator system on the basis of a spatio-temporal graph.

### BACKGROUND

As clean renewable energy, wind energy has been extensively used in recent years. A wind turbine generator system is a large complex electromechanical apparatus to convert wind energy into electric energy, and has a total installed capacity constantly rising. The wind turbine generator system is generally installed in desert, grassland, sea and other areas rich in wind energy resources, where working environments are harsh and operating conditions are complex and changeable. A generator is a core component of the wind turbine generator system, and is likely to break down during long-term operation. For example, a bearing of the generator wears and a winding short-circuits. Once the generator as the core component breaks down, the entire wind turbine generator system is required to be shut down for a repair, causing enormous economic losses. Therefore, by monitoring an operation state of the generator of the wind turbine generator system, a current health state of the wind turbine generator system can be analyzed and evaluated in time and a future operation state can be predicted, so the wind turbine generator system can be ensured to safely, stably and efficiently operate, and economic losses and devastating social impacts caused by the breakdown are avoided. With the progress of a sensor technology and the digitalized, informationized and networked development of an apparatus, a supervisory control and data acquisition (SCADA) system of the wind turbine generator system acquires and accumulates a large amount of operation data of the wind turbine generator system. In combination with the development of a new generation artificial intelligence technology, especially the excellent performance of a deep learning neural network in the field of big data analysis, a method for monitoring a state of a wind turbine generator system on the basis of a deep learning neural network attracts considerable attention and is widely researched. When the state of the wind turbine generator system is monitored by means of the deep learning neural network, current work mainly focuses on modeling and analysis of SCADA data of the wind turbine generator system. For example, a feature data value of the wind turbine generator system during operation in the future is predicted by constructing a normal behavior model of the wind turbine generator system, and the operation state of the wind turbine generator system is online monitored by analyzing a residual between a predicted value and an actual value of data. However, in terms of quality and quantity of acquired data, a performance of the deep learning neural network on monitoring the operation state of the wind turbine generator system has drawbacks of many false alarms, insufficient robustness, etc. In addition, the deep learning neural network is regarded as a black-box model in more work, so it is difficult to effectively explain an analyzed result, and extended application of the deep learning neural network in monitoring the operation state of the wind turbine generator system is limited to a certain extent.

With regard to the wind turbine generator system which is the core component, an explainable intelligent diagnosis method is constructed by fusing knowledge of the field of wind turbine generators and on the basis of the deep learning neural network, which improves a performance of monitoring a state of a generator component. The present disclosure provides an explainable method for monitoring an operation state of a generator of a wind turbine generator system on the basis of a spatio-temporal graph.

### SUMMARY

In order to enhance performance of a deep learning neural network on monitoring a state of a generator of a wind turbine generator system, reduce a false alarm rate, improve robustness, and solve a problem of a lack of explainability of a current artificial intelligence method in apparatus state monitoring, etc., the present disclosure provides an explainable method for monitoring a state of a generator of a wind turbine generator system on the basis of a spatio-temporal graph, which has better monitoring performance, better robustness and stronger explainability.

In order to solve the above technical problem, the present disclosure provides a technical solution as follows:

An explainable method for monitoring a state of a generator of a wind turbine generator system on the basis of a spatio-temporal graph includes steps as follows:

S1: Acquiring supervisory control and data acquisition (SCADA) data in an operation process of the wind turbine generator system, and establishing a normal behavior model by using data of stable operation of the wind turbine generator system within a set range with reference to a wind speed power feature curve.

S2: Taking the generator of the wind turbine generator system as an instance, selecting N features associated with a generator component in the wind turbine generator system, carrying out data cleaning and preprocessing on selected feature data, and obtaining valid data after the data processing.

In a data cleaning stage, data of operation power of the wind turbine generator system of 0, data exceeding a normal operation interval, and data of limited-power operation are deleted.

In a data preprocessing stage, dimensionless processing is carried out on the SCADA data through min-max scaling. It is assumed that in a stable operation state of the wind turbine generator system with reference to wind speed power and other feature curves, the SCADA system acquires T pieces of sample data, x^{i,j} is a jth piece of selected SCADA feature data in an ith sample,

$${x}_{min}^{j} and {x}_{max}^{j}$$

are respectively a minimum and a maximum in the jth piece of SCADA feature data, and data after standardization of the selected SCADA feature data is as follows:

$${x}_{nrom}^{i , j} = \frac{{x}^{i , j} - {x}_{min}^{j}}{{x}_{max}^{j} - {x}_{min}^{j}} …… ∀ i , j . \qquad ( 1 )$$

S3: Embedding the SCADA data subjected to data processing in S2 into spatio-temporal graph data by using prior knowledge related to the wind turbine generator system and including a causal relation between an internal structure of the wind turbine generator system and a monitoring variable, and constructing directed graph data Gi=(V, E) at ith moment including the prior knowledge, where V={v₁, . . . , v_{N}} is a set of all nodes in a directed graph, v₁, . . . , v_{N} are nodes representing the selected N SCADA features in the graph, and E is a set of edge relations and represents a relation between one node and adjacent nodes. A graph construction method of the prior knowledge includes two steps as follows: step 1: carrying out feature mapping on the data collected by the SCADA system, where related features corresponding to the generator components of the wind turbine generator system reflect respective operation conditions of different components. Step 2: classifying the SCADA data into environment information (such as a wind speed and an environment temperature), and internal information (such as a main shaft rotation speed, and a generator winding temperature) and output variable information (such as active power) of the wind turbine generator system according to the prior knowledge. These three categories of information has relations that the environment information influences the internal information of the wind turbine generator system, and the internal information influences the output variable information of the wind turbine generator system. A connection relation between the nodes is formed according to the prior knowledge, and directed graph Gi is formed by fusing the SCADA feature data. Feature data of the ith sample is represented by feature matrix Xᵢ∈R^{N×F}, where F represents a feature dimension of the node. A relation between the nodes is represented by adjacent matrix A∈R^{N×N}. Formed directed graph data G is divided according to a time window, a window length is set as L, and a step length is set as 1. Directed graph data G_{1:L}:[G₁, G₂, . . . , Gᵢ, . . . , G_{L}] of a sequence is formed.

S4: Predicting, with regard to constructed spatio-temporal graph data sequence G_{1:L}, a feature value of each node at a subsequent moment by means of a spatio-temporal information fused graph neural network and by fusing features of stable operation of the wind turbine generator system within a set range with reference to a wind speed power feature curve, computing a residual between a predicted value and an actual measured value of each node, computing an overall feature residual of the wind turbine generator system and a residual of each monitoring point through an exponentially weighted moving average (EWMA) control chart method, selecting appropriate control chart parameters, setting thresholds of a total graph and each node of the generator, and monitoring the state of the generator of the wind turbine generator system. The full-graph-level residual reflects the overall operation state of the generator of the wind turbine generator system. The node-level residual reflects the operation state of the related components of the generator of the wind turbine generator system mapped by the corresponding SCADA feature. Moreover, the node-level state monitoring result is in the graph, and explainability of the state monitoring result is enhanced according to an abnormal information transmission relation formed in chronological order.

Further, in S4, a prediction process of each node feature value is as follows:
the spatio-temporal information fused graph neural network is composed of 4 parts of a graph attention network, a global and local attention embedding layer, a long short-term memory (LSTM) network and a linear regression layer. The graph attention network transfers and updates node information (Xᵢ∈R^{N×F}) in single directed spatio-temporal graph data Gi by an inter-node attention mechanism by using a topological relation (adjacent matrix A∈R^{N×N}) of the prior knowledge, such that each node effectively captures space information in the data. In a node set of v₁, . . . , vᵤ, . . . , v_{N}, with vᵤ as an instance, vᵤ∈V serves as a center node and has node feature xᵤ⊂Xᵢ, Nᵤ is an adjacent node set that transmits information to vᵤ, and vᵣ∈Nᵤ is one of the nodes in the set and has node feature xᵣ⊂Xᵢ. A graph attention network process is divided into two steps as follows:

Step 1: computing a normalized attention coefficient between the nodes by means of a graph attention mechanism, where a normalized attention coefficient of transmission from node vᵣ to center node vᵤ is as follows:

$${α}_{ur} = \frac{exp ( LeakReLU ( {a}^{T} \cdot [ {W}_{{x}_{u}} ‖ {W}_{{x}_{r}} ] ) )}{{\sum }_{k ∈ {N}_{u}} exp ( LeakReLU ( {a}^{T} \cdot [ W ‖ {W}_{{x}_{r}} ] ) )} . \qquad ( 2 )$$

In the formula, a^{T} is a learnable neural network parameter matrix, ∥ represents a matrix splicing operation, LeakReLU( ) is a nonlinear activation function, Wₓ_{ᵤ}, Wₓ_{ᵣ} and Wₓ_{ₖ} respectively represent dimensionality transformation learnable matrices of node vᵤ, node vᵣ and node vₖ, and αᵤᵣ is a normalized attention coefficient between node vᵤ and node vᵣ.

Step 2: integrating a graph representation network through a multi-head attention method, splicing all node features in a single directed graph through the matrix splicing operation, and obtaining a full-graph feature after integration of space information of all the nodes as follows:

$${P}_{i} = {{\vert \vert}^{N}}_{n = 1} \frac{1}{M} ReLU ( {\sum }_{m = 1}^{M} {\sum }_{k ∈ {N}_{u}} {α}_{uk}^{m} {W}_{{x}_{k}} ) . \qquad ( 3 )$$

In the formula, Pᵢ is the full-graph feature having the space information and integrated by the graph attention network, and M is a number of attention heads.

Carrying out spatio-temporal feature fusion on full-graph feature Pᵢ of the single directed graph by the global and local attention embedding layer and the long short-term memory (LSTM) network by using time sequence information in a graph sequence. The global and local attention embedding layer is expressed as follows:

$${β}_{i} = \frac{exp ( {V}^{T} tanh ( {P}_{i} ) )}{{\sum }_{i = 1}^{L} exp ( {V}^{T} tanh ( {P}_{i} ) )} . \qquad ( 4 )$$

In the formula, βᵢ is a normalized local importance coefficient of directed spatio-temporal graph data at an ith moment in an entire window graph sequence, and V^{T} tan h(Pᵢ) represents a corresponding local feature at each moment in window sequence (t=1, 2, 3, . . . , i, . . . , L).

Carrying out a splicing operation after normalized local importance coefficient at each moment in the window sequence is obtained, forming a global feature representing overall window information, and combining the global feature with local feature Pᵢ, which is expressed as follows:

$$γ = [ {β}_{1} ‖ {β}_{2} ‖ … ‖ {β}_{L} ] and , \qquad ( 5 )$$

$${d}_{i} = [ {P}_{i} ‖ γ ] . \qquad ( 6 )$$

In the formulas, γ is the global feature of the entire window information, dᵢ is a feature after global and local information fusion, and a fused feature sequence of [d₁, d₂, . . . , dᵢ, . . . , d_{L}] is output by the global and local attention embedding layer.

Inputting the output sequence into the long short-term memory network layer for spatio-temporal feature fusion, where a long short-term memory network process is expressed as follows:

$${I}_{i} = σ ( {d}_{i} {W}_{dI} + {h}_{i - 1} {W}_{hI} + {C}_{i - 1} {W}_{ci} + {b}_{i} ) , \qquad ( 7 )$$

$${F}_{i} = σ ( {d}_{i} {W}_{df} + {h}_{i - 1} {W}_{hf} + {C}_{i - 1} {W}_{cf} + {b}_{f} ) , \qquad ( 8 )$$

$${C}_{i} = {I}_{i} tanh ( {d}_{i} {W}_{dc} + {h}_{i - 1} {W}_{hc} + {b}_{c} ) + {F}_{i} {C}_{i - 1} , \qquad ( 9 )$$

$${O}_{i} = σ ( {d}_{i} {W}_{do} + {h}_{i - 1} {W}_{ho} + {C}_{i - 1} {W}_{co} + {b}_{o} ) , and \qquad ( 10 )$$

$${h}_{i} = {O}_{i} tanh ( {C}_{i} ) . \qquad ( 11 )$$

In formulas, W is a learnable matrix of an input gate, a forget gate and a control gate in a long short-term memory network unit, b is a corresponding bias matrix, Iᵢ is an input gate feature in the long short-term memory network, Fᵢ is a forget gate feature, Cᵢ is a hidden state feature in the long short-term memory network, Oᵢ is an output gate feature, σ represents nonlinear activation function Sigmoid( ) tan h( ) is a nonlinear activation function, and hᵢ represents spatio-temporal fusion feature output after global and local fused feature sequence [d₁, d₂, . . . , dᵢ, . . . d_{L}] passes through the long short-term memory network.

Predicting a feature value of each node in directed graph G at a subsequent moment by causing output spatio-temporal fusion feature hᵢ to pass through two fully connected layers.

Training is carried out by means of T pieces of sample data of normal behaviors collected by the SCADA system of the wind turbine generator system, where first 70% data is used as a training set and last 30% data is used as a test set. Back propagation training is carried out on the spatio-temporal information fused graph neural network by means of an Adam optimizer and a mean square error loss function. Appropriate training parameters are selected according to loss function results of the training set and the test set, and a spatio-temporal information fused graph neural network model is obtained.

Further, in S4, a process of carrying out full-diagram-level state monitoring, computing a predicted residual of each node feature in the directed graph, and reflecting an operation state of the generator of the wind turbine generator system, that is, a full-diagram-level state monitoring result is expressed by a formula as follows:

$${RMSE}_{i}^{all} = \sqrt{\frac{1}{Q} \cdot \frac{1}{N} {\sum }_{i - \frac{Q}{2}}^{i + \frac{Q}{2}} {\sum }_{n = 1}^{N} {( {\hat{y}}_{i}^{n} - {y}_{i}^{n} )}^{2}} . \qquad ( 12 )$$

In the formula,

$${RMSE}_{i}^{all}$$

represents a residual of the full-graph-level state monitoring, Q is a size of a window for computing the residual, and

$${\hat{y}}_{i}^{n} and {y}_{i}^{n}$$

respectively represent a predicted value and an actual measured value of a feature at node vₙ of a spatio-temporal graph.

Setting a threshold for full-graph-level state monitoring result

$${RMSE}_{i}^{all}$$

by using an exponentially weighted moving average (EWMA) control chart is expressed by formulas as follows:

$${E}_{i}^{all} = {λ}^{all} {\overline{r}}_{i}^{all} + ( 1 - {λ}^{all} ) {E}_{i - 1}^{all} , and \qquad ( 13 )$$

$${Thr}^{all} ( i ) = {μ}_{r}^{all} + {K}^{all} {σ}_{r}^{all} \sqrt{\frac{{λ}^{all}}{2 - {λ}^{all}} [ 1 - {( 1 - {λ}^{all} )}^{2 i} ]} . \qquad ( 14 )$$

In the formulas, r̅ᵢ̅^{all} is an average of predicted residuals of full-graph-level state monitoring results of an ith sample graph sequence, λ^{all}∈[0, 1] represents an importance degree coefficient of a current window, μᵣ^{all} and σᵣ^{all} respectively represent a standard deviation and an average of full-graph-level state monitoring residual

$${RMSE}_{i}^{all}$$

Kall is a coefficient of an upper control limit (UCL) of the exponentially weighted moving average (EWMA) control chart, an appropriate coefficient is selected to carry out modeling analysis on the entire wind turbine generator system in a normal behavior, and when a predicted residual of the full-graph-level state monitoring continuously exceeds the upper control limit for 3 times, it is determined that the operation state of the generator of the wind turbine generator system is abnormal.

Further, in S4, a process of carrying out node-level state monitoring, constructing node-level abnormal information, determining whether a fault occurs according to whether a transmission relation exits in chronological order, further enhancing explainability and robustness of monitoring of the operation state of the wind turbine generator system to a certain extent, and reducing false alarms is as follows:

Step 1: computing residual

$${RMSE}_{i}^{n}$$

of the node-level state monitoring through an EWMA control chart method, and setting a threshold for each feature as follows:

$${RMSE}_{i}^{all} = \sqrt{\frac{1}{Q} {\sum }_{i - \frac{Q}{2}}^{i + \frac{Q}{2}} {\sum }_{n = 1}^{N} {( {\hat{y}}_{i}^{n} - {y}_{i}^{n} )}^{2}} , \qquad ( 15 )$$

$${E}_{i}^{n} = {λ}^{n} {\overline{r}}_{i}^{n} + ( 1 - {λ}^{n} ) {E}_{i - 1}^{n} , and \qquad ( 16 )$$

$${Thr}^{n} ( i ) = {μ}_{r}^{n} + {K}^{n} {σ}_{r}^{n} \sqrt{\frac{{λ}^{n}}{2 - {λ}^{n}} [ 1 - {( 1 - {λ}^{n} )}^{2 i} ]} . \qquad ( 17 )$$

Obtaining a state monitoring threshold of each node, and reflecting, in a case that residual RMSEᵢⁿ of an nth node exceeds Thrⁿ(i) for 3 continuous times, that the component corresponding to the related feature of the generator of the wind turbine generator system corresponding to the node is abnormal.

Step 2: determining, in combination with a space structure of directed graph data Gᵢ constructed by the prior knowledge in S3 and an abnormal result of a multi-node operation state monitoring in the first step, whether a fault occurs by determining whether a transmission relation exists in chronological order includes: regarding, when a node has an abnormal condition, the node as a potential abnormal node, transmitting information to nodes adjacent to the node in directed graph data Gᵢ, making a sequence abnormal, and so on. If a complete fault information transmission chain is subsequently formed in the directed graph, it is indicated that a fault really occurs in this abnormal situation. Moreover, an initial abnormal node of the abnormal information transmission chain is close to a fault source, and directly indicates a specific component or position where the fault occurs.

A technical idea of the present disclosure is as follows: by using data collected by a supervisory control and data acquisition (SCADA) system of the wind turbine generator system, and taking a generator component of the wind turbine generator system as a monitoring object, data understanding is carried out first, and features associated with the generator in the wind turbine generator system are selected. Then, data processing is carried out, and data cleaning and preprocessing are carried out on the selected data. A directed graph is constructed for the selected SCADA features by using the prior knowledge, and a directed graph sequence is formed through a moving window technology. Directed graph and node features at a subsequent moment are predicted by means of the spatio-temporal graph network composed of the graph attention network, the global and local attention embedding network, the long short-term memory network and the fully connected layers, and the residual between the predicted value and the actual measured value of each node is computed. Full-graph-level and node-level state monitoring is carried out on the wind turbine generator system in a case of normal behavior modeling through an exponentially weighted moving average (EWMA) control chart method. Full-graph-level state monitoring reflects the operation state of the generator component of the wind turbine generator system. Node-level state monitoring reflects the SCADA features corresponding to the node and the operation state of the mapped component. False alarms are eliminated according to the node-level state monitoring result at abnormal alarm moments of different nodes and according to whether a fault information transmission chain is formed in the spatio-temporal graph, and robustness of the operation state monitoring result is enhanced.

### BRIEF DESCRIPTION OF THE DRAWINGS

FIG. 1A and FIG. 1B are an overall framework diagram of an explainable method for monitoring a state of a generator of a wind turbine generator system on the basis of a spatio-temporal graph.

FIG. 2 is a wind speed power curve graph of a wind turbine generator system after data cleaning.

FIG. 3 is a framework diagram of a prior knowledge of a wind turbine generator system.

FIG. 4 is a diagram showing a relation between supervisory control and data acquisition (SCADA) features of a wind turbine generator system with embedded prior knowledge.

FIG. 5 is a directed graph constructed on the basis of prior knowledge and SCADA features of a wind turbine generator system.

FIG. 6 is a diagram showing a full-graph-level state monitoring result of a wind turbine generator system.

FIG. 7 is a schematic diagram of a transmission relation formed by node-level abnormal information in chronological order.

FIG. 8 is a diagram of a node-level state monitoring result before a fault occurs on a generator of a wind turbine generator system.

FIG. 9 is a node-level state monitoring alarm time sequence diagram of a generator of a wind turbine generator system.

FIG. 10 is a schematic diagram of a transmission relation formed in chronological order of a node-level state monitoring result of a generator of a wind turbine generator system.

### DETAILED DESCRIPTIONS OF THE EMBODIMENTS

The present disclosure will be further described below in combination with the accompanying drawings.

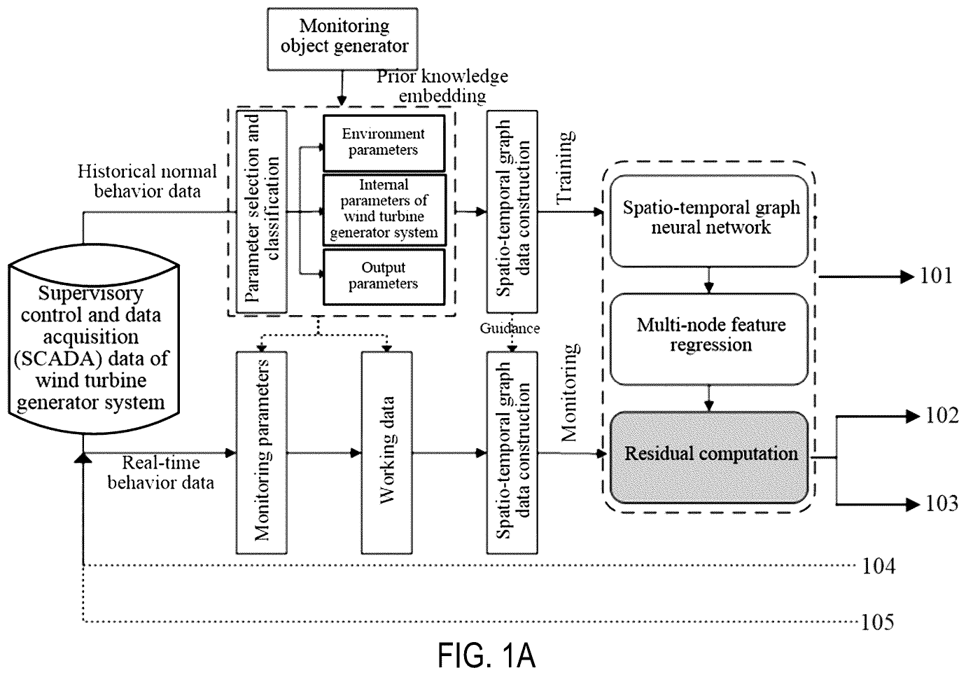

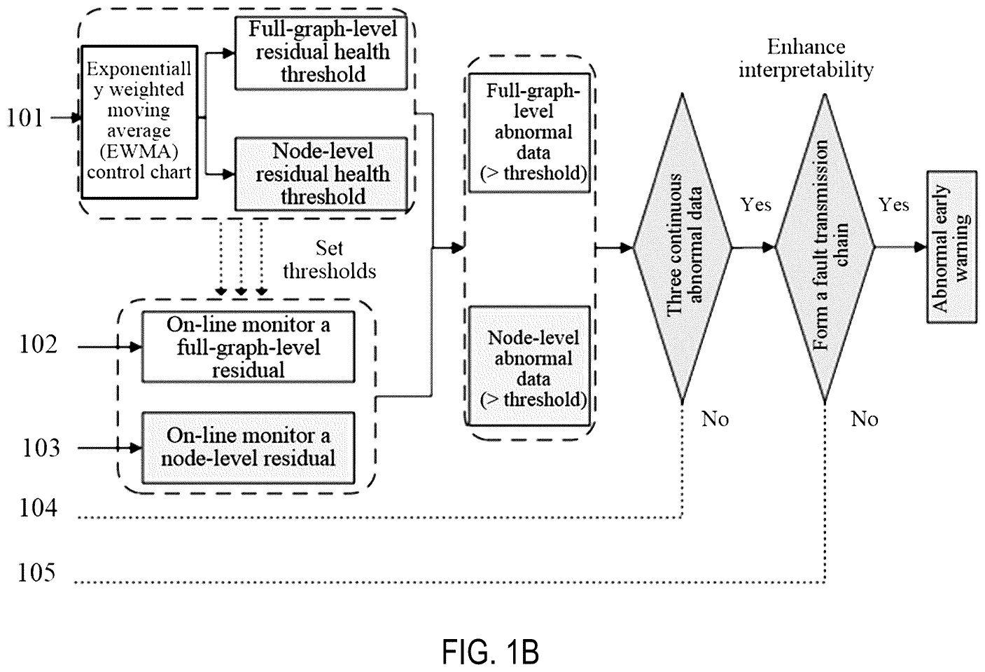

With reference to FIGS. 1-10, an explainable method for monitoring a state of a wind turbine generator system on the basis of a spatio-temporal graph is shown. An overall framework of the method is as shown in FIG. 1 and FIG. 1B. The method includes steps as follows:

S1: Acquire data collected by a supervisory control and data acquisition (SCADA) system in an operation process of the wind turbine generator system.

S2: Take a generator component of the wind turbine generator system as an instance, carry out data understanding first, specifically, select N features associated with the generator component of the wind turbine generator system from the SCADA data; and carry out data processing, specifically, carry out data cleaning and preprocessing on selected feature data, and obtain valid data after the data processing.

In a data cleaning stage, data of operation power of the wind turbine generator system of 0, data exceeding a normal operation interval, and data of limited-power operation are deleted.

In a data preprocessing stage, dimensionless processing is carried out on the SCADA data through a Min-Max Scaling method. It is assumed that there are T samples of normal behaviors collected by the SCADA system of the wind turbine generator system. In such sample data, i represents an ith sample in a T-sample sequence, and is used to describe an operation state of the wind turbine generator system at an i moment. Each sample includes a series of SCADA feature data, where a jth piece of feature data represents an jth SCADA feature value at the moment, x^{i,j} is a jth piece of selected SCADA feature data at an ith moment,

$${x}_{min}^{j} and {x}_{max}^{j}$$

are respectively a minimum and a maximum in the jth piece of SCADA feature data, and data after standardization of the selected SCADA feature data is as follows:

$${x}_{min}^{j} and {x}_{max}^{j}$$

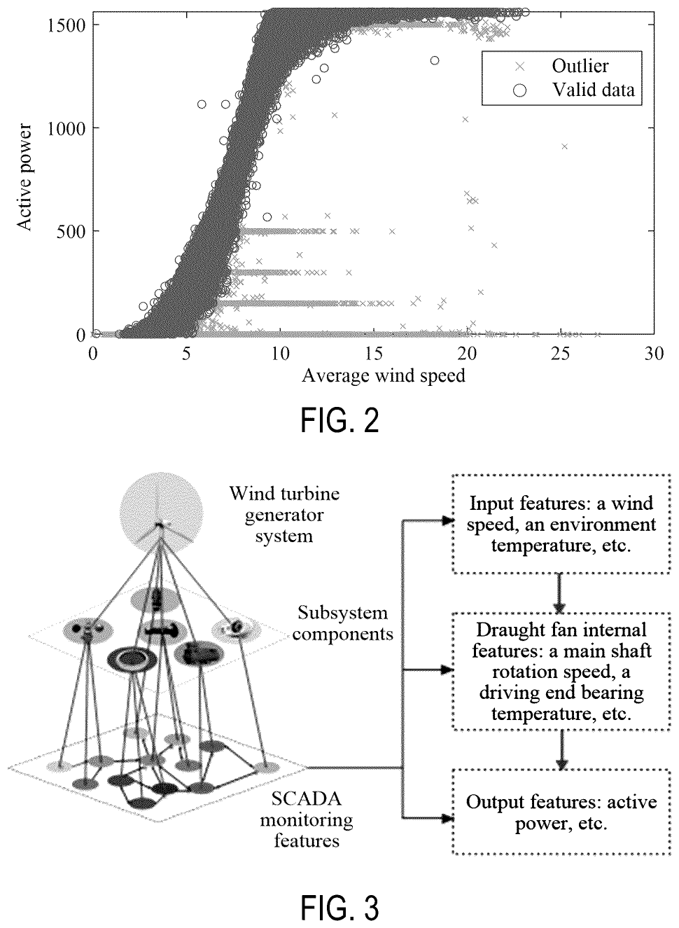

In the data cleaning part, some limited power data and abnormal point data are deleted. Further, the SCADA data is normalized (as shown in FIG. 2).

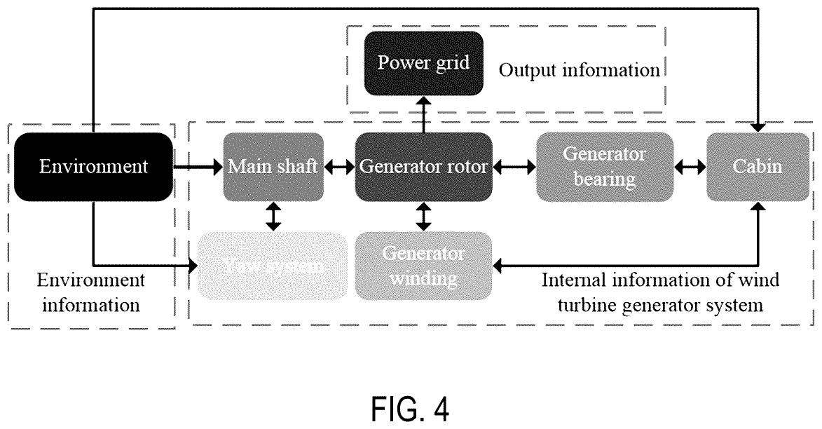

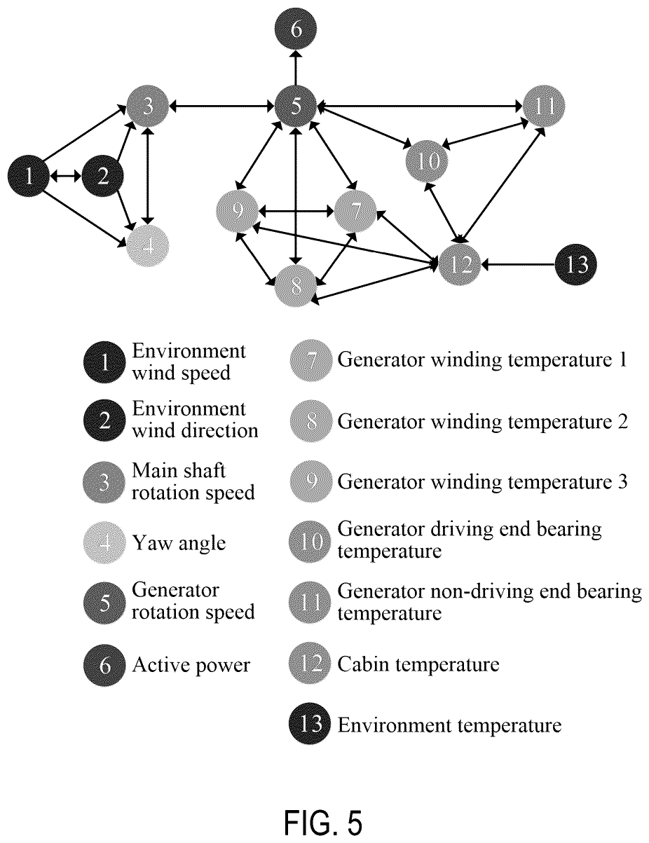

S3: Provide a method for constructing a spatio-temporal graph by embedding prior knowledge of a wind turbine generator system (as shown in FIG. 3). A graph construction method of the prior knowledge includes two steps as follows: step 1: carry out feature mapping on the data collected by the SCADA system, where related features corresponding to the generator components of the wind turbine generator system reflect respective operation conditions of different components. Step 2: classify the SCADA features into environment information (such as a wind speed and an environment temperature), and internal information (such as a main shaft rotation speed, and a generator winding temperature) and output variable information (such as active power) of the wind turbine generator system according to the prior knowledge. These three categories of information has relations that the environment information influences the internal information of the wind turbine generator system, and the internal information influences the output variable information. The SCADA data standardized in S2 is embedded into spatio-temporal graph data by using prior knowledge (as shown in FIG. 4), and directed graph data Gᵢ=(V, E) at an ith moment including the prior information is constructed (as shown in FIG. 5). Specifically, V={v₁, . . . , v_{N}} is a set of all nodes in a directed graph, v₁, . . . , v_{N} are nodes representing the selected N SCADA features in the graph, and E is a set of edge relations and represents a relation between one node and adjacent nodes. Feature data at an i moment is represented by feature matrix Xᵢ∈R^{N×F}, where F represents a feature quantity of the node. A relation between the nodes is represented by adjacent matrix A∈R^{N×N}. Formed directed graph data G is divided according to a time window, a window length is set as L, and a step length is set as 1. Directed graph data G_{1:L}:[G₁, G₂, . . . , Gᵢ, . . . , G_{L}] of a sequence is formed.

S4: Predict, by means of a spatio-temporal information fused graph neural network composed of 4 parts of a graph attention network, a global and local attention embedding layer, a long short-term memory (LSTM) network and a linear regression layer, a feature value of each node at a subsequent moment of a spatio-temporal graph data sequence constructed in a normal behavior of the wind turbine generator system, compute a residual between a predicted value and a true value of each node, compute a residual of each node in the normal behavior and an average-weighted full-graph-level residual of each node through an exponentially weighted moving average (EWMA) control chart method, set thresholds of each node and the full graph by selecting appropriate control chart parameters, and carry out node-level state monitoring and full-graph-level state monitoring of the wind turbine generator system.

Input the directed graph data sequence into a first part of the spatio-temporal information fused graph neural network, and extract space information from the directed graph by a multi-head graph attention network. A computation process is as follows:

$$α = \frac{exp ( L e a k R e L U ( {a}^{T} \cdot [ {W}_{{x}_{u}} \vert \vert {W}_{{x}_{r}} ] ) )}{{\sum }_{k ∈ {N}_{u}} exp ( L e a k R e L U ( {a}^{T} \cdot [ {W}_{{x}_{u}} \vert \vert {W}_{{x}_{k}} ] ) )} , and \qquad ( 2 )$$

$${P}_{i} = {{\vert \vert}^{N}}_{n = 1} \frac{1}{M} ReLU ( {\sum }_{m = 1}^{M} {\sum }_{k ∈ {N}_{u}} {α}_{uk}^{m} {W}_{{x}_{k}} ) . \qquad ( 3 )$$

Obtain full-graph feature [P₁, P₂, . . . , Pᵢ, . . . , P_{L}] of a sequence having space information, put the full-graph feature into a global and local attention embedding layer for global and local feature extraction of a time sequence window. Computation formulas are as follows:

$${β}_{i} = \frac{exp ( {V}^{T} tanh ( {P}_{i} ) )}{{\sum }_{i = 1}^{L} exp ( {V}^{T} tanh ( {P}_{i} ) )} , \qquad ( 4 )$$

$$γ = [ {β}_{1} ‖ {β}_{2} ‖ … ‖ {β}_{L} ] , and \qquad ( 5 )$$

$${d}_{i} = [ {P}_{i} \vert \vert γ ] . \qquad ( 6 )$$

Place obtained fusion sequence [d₁, d₂, . . . , dᵢ, . . . , d_{L}] into the long short-term memory network layer for spatio-temporal feature fusion. Computation formulas of a long short-term memory network process are expressed as follows:

$${I}_{i} = σ ( {d}_{i} {W}_{dI} + {h}_{i - 1} {W}_{hI} + {C}_{i - 1} {W}_{c i} + {b}_{i} ) , \qquad ( 7 )$$

$${F}_{i} = σ ( {d}_{i} {W}_{df} + {h}_{i - 1} {W}_{h f} + {C}_{i - 1} {W}_{c f} + {b}_{f} ) , \qquad ( 8 )$$

$${C}_{i} = {I}_{i} tanh ( {d}_{i} {W}_{d c} + {h}_{i - 1} {W}_{h c} + {b}_{c} ) + {F}_{i} {C}_{i - 1} , \qquad ( 9 )$$

$${O}_{i} = σ ( {d}_{i} {W}_{d o} + {h}_{i - 1} {W}_{h o} + {C}_{i - 1} {W}_{c o} + {b}_{o} ) , and \qquad ( 10 )$$

$${h}_{i} = {O}_{i} tanh ( {C}_{i} ) . \qquad ( 11 )$$

Predict a feature value of each node in directed graph G at a subsequent moment by causing output spatio-temporal fusion feature hᵢ to pass through two fully connected layers.

Carry out full-graph-level state monitoring on the predicted node features, and carry out computation by means of a weighted residual of all node features in the directed graph. A computation formula is expressed as follows:

$$R M S {E}_{i}^{all} = \sqrt{\frac{1}{Q} \cdot \frac{1}{N} {\sum }_{i - \frac{Q}{2}}^{i + \frac{Q}{2}} {\sum }_{n = 1}^{N} {( {\hat{y}}_{i}^{n} - {y}_{i}^{n} )}^{2}} . \qquad ( 12 )$$

Set a threshold for residual

$$R M S {E}_{i}^{all}$$

of the full-graph-level state monitoring through an exponentially weighted moving average (EWMA) control chart method, which is expressed as follows:

$${E}_{i}^{all} = {λ}^{all} {\overline{{r}_{i}}}^{all} + ( 1 - {λ}^{all} ) {E}_{i - 1}^{all} , and \qquad ( 13 )$$

$$Th {r}^{all} ( i ) = {μ}_{r}^{all} + {K}^{all} {σ}_{r}^{all} \sqrt{\frac{{λ}^{all}}{2 - {λ}^{all}} [ 1 - {( 1 - {λ}^{all} )}^{2 i} ]} . \qquad ( 14 )$$

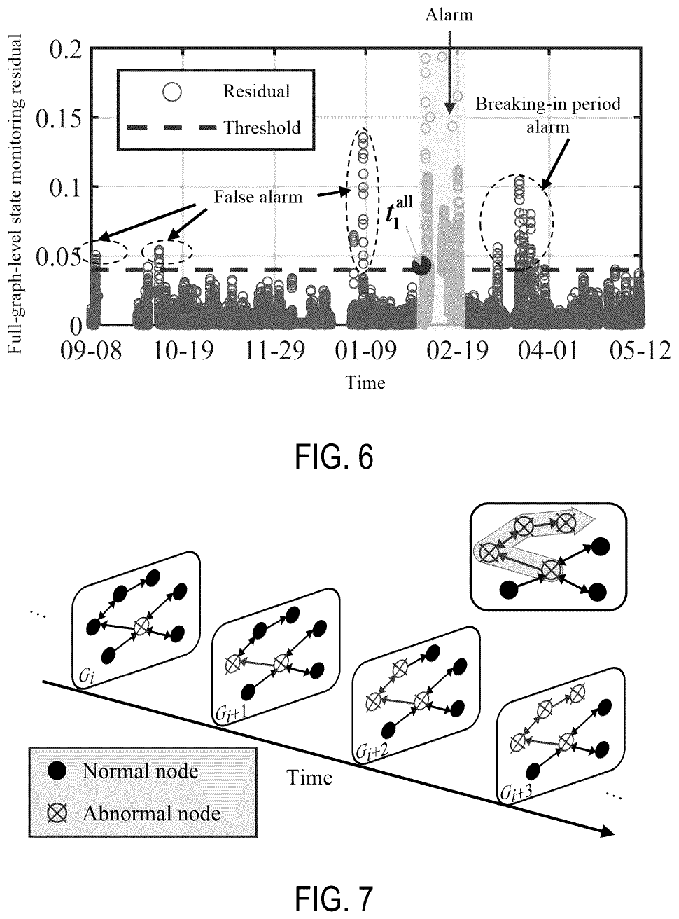

Determine, in a case that the residual of full-graph-level state monitoring continuously exceeds the upper control limit for 3 times, that the wind turbine generator system is in an abnormal state (as shown in FIG. 6).

Carry out node-level state monitoring on the predicted node features, and carry out computation by using the residual of each node feature in the directed graph. A computation formula is expressed as follows:

$$R M S {E}_{i}^{n} = \sqrt{\frac{1}{Q} {\sum }_{i - \frac{Q}{2}}^{i + \frac{Q}{2}} {( {\hat{y}}_{i}^{n} - {y}_{i}^{n} )}^{2}} . \qquad ( 15 )$$

Set a threshold of an upper control limit (UCL) for residual

$$R M S {E}_{i}^{n}$$

of node-level state monitoring by using an exponentially weighted moving average (EWMA) control chart as follows:

$${E}_{i}^{n} = {λ}^{n} {\overline{{r}_{i}}}^{n} + ( 1 - {λ}^{n} ) {E}_{i - 1}^{n} , and \qquad ( 16 )$$

$$Th {r}^{n} ( i ) = {μ}_{r}^{n} + {K}^{n} {σ}_{r}^{n} \sqrt{\frac{{λ}^{n}}{2 - {λ}^{n}} [ 1 - {( 1 - {λ}^{n} )}^{2 i} ]} . \qquad ( 17 )$$

Obtain a node-level state monitoring threshold of each node, and reflect, in a case that residual

$$R M S {E}_{i}^{n}$$

of an nth node exceeds Thrⁿ(i) for 3 continuous times, that a component of the wind turbine generator system mapped by the node has an abnormal condition (as shown in FIG. 7).

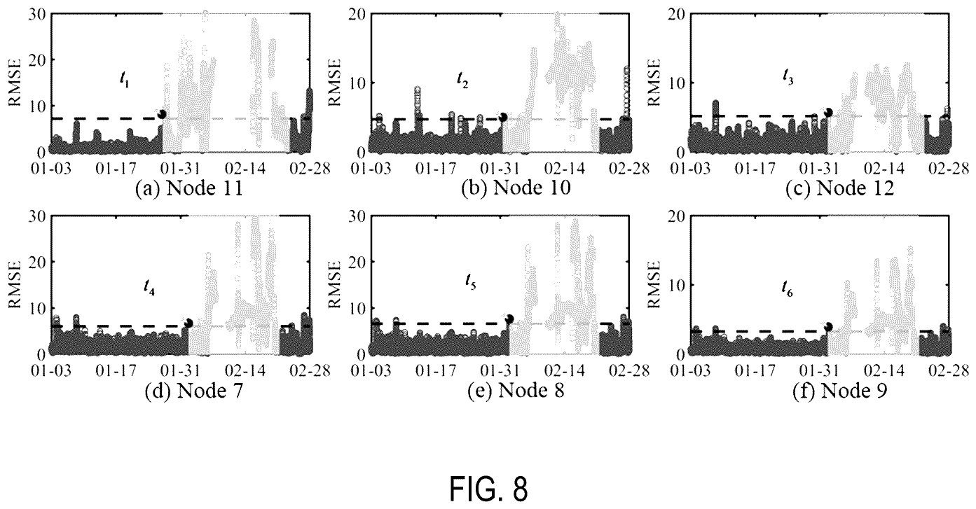

Determine, in combination with a space structure of directed graph data Gᵢ constructed by the prior knowledge and a multi-node state monitoring result in S3, whether a fault occurs by determining whether a transmission relation exists in chronological order (as shown in FIG. 7), which includes: regard, when a node has an abnormal condition, the node as a potential abnormal node, transmit information to nodes adjacent to the node in directed graph data Gᵢ, make a sequence abnormal, and so on. If a complete fault transmission chain is subsequently formed in the directed graph, it is indicated that the fault of the generator really occurs. Moreover, a starting point of the abnormal information transmission chain is close to a fault source, and is highly related to a fault component of the wind turbine generator system (as shown in FIGS. 8, 9 and 10).

According to the present disclosure, the explainable method for monitoring a state of a wind turbine generator system on the basis of a spatio-temporal graph is verified by utilizing on-line operation SCADA data of a double-fed asynchronous wind turbine generator system in southeast China. An overall framework flow is as shown in FIG. 1A and FIG. 1B, and a specific process is as follows:
1) Acquire data every 10 seconds by means of a SCADA system on a wind turbine generator system.
2) Take a generator component of the wind turbine generator system as a monitoring object, carry out data understanding first, and select 13 features associated with the generator of the wind turbine generator system. Carry out data processing, specifically, carry out abnormal data cleaning and preprocessing on the selected data (shown in FIG. 2).
3) As shown in FIG. 3, map SCADA features to related generator components of the wind turbine generator system through a wind turbine generator system prior knowledge method, further, associate the selected SCADA features with wind turbine generator system components (as shown in FIG. 4), and finally embed SCADA data into the associated wind turbine generator system components to form spatio-temporal graph data (as shown in FIG. 5).
4) Input a spatio-temporal graph data sequence into a spatio-temporal information fused graph neural network for feature value prediction.
5) Carry out full-graph-level state monitoring by using predicted feature values, and obtain overall operation state information of a generator subsystem.
6) On the basis of the full-graph-level state monitoring, carry out node-level state monitoring by using the predicted feature values, and further determine, by using the node-level state monitoring result, whether a fault occurs by determining whether a transmission relation exists in chronological order.

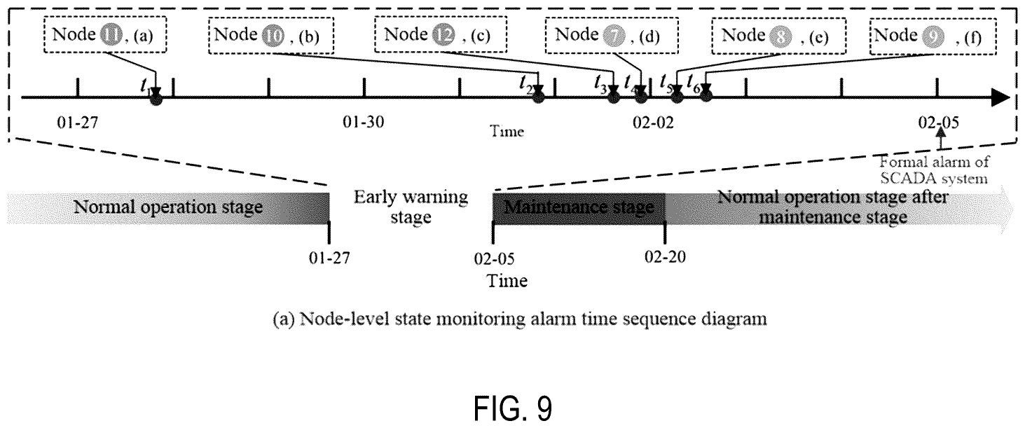

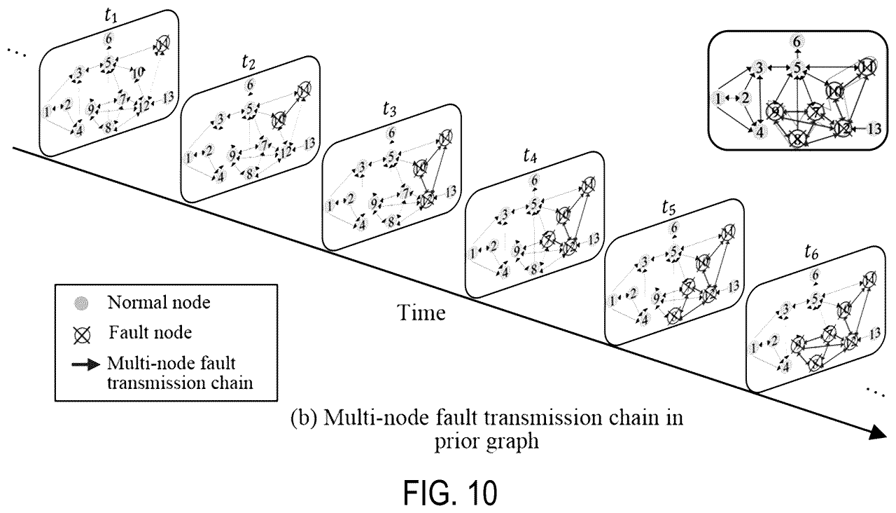

Obtain a full-graph-level state monitoring result (as shown in FIG. 6), where it can be seen from the figure that an abnormal alarm moment of graph-level state monitoring is relatively late, and there are many false alarms. Further, form a schematic diagram of a transfer relation by using node-level abnormal information in chronological order (as shown in FIG. 7), compute a residual of each node, set a UCL threshold line through an EWMA control chart method for node-level state monitoring, and obtain a state monitoring result of multi-node feature values of the related generator components of the wind turbine generator system (as shown in FIG. 8). It can be seen from the figure that an abnormal alarm sequence and result of node-level state monitoring are as follows: a non-driving end bearing temperature feature of the generator is abnormal first, it is reflected that a potential fault occurs on a non-driving end bearing, the fault information is gradually transmitted to a generator driving end bearing and rotor, which abnormally operate, through a generator rotor, winding, etc. A conclusion obtained from analysis of the graph data is that the bearing temperature at the non-driving end of the generator is abnormal. Due to the transmission of fault information, features of adjacent nodes, such as a generator driving end bearing temperature, a cabin temperature and a winding temperature are gradually abnormal. A result of generator fault diagnosis analysis on the basis of a spatio-temporal graph is consistent with an actual situation. A plurality of nodes gradually form a transmission relation in chronological order (as shown in FIGS. 9 and 10). The explainable method for monitoring a state of a wind turbine generator system on the basis of a spatio-temporal graph is effectively verified.

The present disclosure has beneficial effects as follows: the SCADA data is embedded into a spatial structure directed graph by means of the prior knowledge, the explainable method for monitoring a state of a generator of a wind turbine generator system on the basis of a spatio-temporal graph is constructed, and the explainability and robustness of intelligent operation and maintenance of the wind turbine generator system are improved.

What is claimed is:

1. An explainable method for monitoring a state of a generator of a wind turbine generator system on the basis of a spatio-temporal graph, comprising steps as follows:
S1: acquiring data collected by a supervisory control and data acquisition (SCADA) system, that is, SCADA data, in an operation process of the wind turbine generator system, establishing a normal behavior model by using data of stable operation of the wind turbine generator system within a set range with reference to a wind speed power feature curve, and monitoring the state;
S2: selecting N features associated with the wind turbine generator system from the SCADA data, carrying out data cleaning and preprocessing on selected feature data, and obtaining valid data after the data processing;
S3: embedding the SCADA data subjected to the data cleaning and preprocessing into spatio-temporal graph data by using prior knowledge related to the wind turbine generator system and comprising a causal relation between an internal structure of the generator system and a monitoring variable, and constructing directed graph data Gi=(V, E) of an ith sample comprising prior information, wherein V={v₁, . . . , v_{N}} is a set of all nodes in a directed graph, and v₁, . . . , v_{N} are nodes of the selected N SCADA features; E is a set of edge relations and represents a relation in which a node transmits information to adjacent nodes;
directed graph data Gi is formed according to the prior knowledge and by fusing a connection relation between the nodes and the SCADA data features; feature data at an ith sample moment by is represented by feature matrix Xᵢ∈R^{N×F}, wherein F represents a feature quantity of the nodes; a relation between the nodes is represented by adjacent matrix A∈R^{N×N}; the formed directed graph data G is divided according to a time window, wherein a window length is set as L, and a step length is set as 1; and directed graph data G_{1:L}[G₁, G₂, . . . , Gᵢ, . . . , G_{L}] having time sequence information is formed; and
S4: predicting, with regard to constructed spatio-temporal directed graph data sequence GIL, a feature value of each node at a subsequent moment by means of a spatio-temporal information fused graph neural network and by fusing features of stable operation of the wind turbine generator system within a set range with reference to a wind speed power feature curve, computing a residual of a predicted feature value and an actual measured value of each node, computing an overall feature residual of the wind turbine generator system and a residual of a feature of each node through an exponentially weighted moving average (EWMA) control chart method, selecting appropriate control chart parameters, setting thresholds of a total graph and each node of the generator of the wind turbine generator system, and monitoring the state of the wind turbine generator system.

2. The explainable method for monitoring a state of a generator of a wind turbine generator system on the basis of a spatio-temporal graph according to claim 1, wherein in S2:
in a data cleaning stage, data of operation power of the wind turbine generator system of 0, data exceeding a normal operation interval, and data of limited-power operation are deleted; and
in a data preprocessing stage, dimensionless processing is carried out on the SCADA data through min-max scaling; it is assumed that normal behaviors collected by the SCADA system of the wind turbine generator system have T pieces of sample data, and in the sample data, i represents an ith piece of sample data and is used to describe an operation state of the wind turbine generator system at a corresponding moment of an ith sample; each sample comprises a series of SCADA feature data, wherein an jth piece of feature data represents a jth SCADA feature value at the moment; and x^{i,j} is an jth piece of SCADA feature data in the ith sample,
$${x}_{min}^{j} and {x}_{max}^{j}$$
are a minimum and a maximum in the jth piece of SCADA feature data, and data after standardization of a selected SCADA feature is as follows:
$${x}_{norm}^{i , j} = \frac{{x}^{i , j} - {x}_{min}^{j}}{{x}_{max}^{j} - {x}_{min}^{j}} … ∀ i , j . \qquad ( 1 )$$

3. The explainable method for monitoring a state of a generator of a wind turbine generator system on the basis of a spatio-temporal graph neural network according to claim 1, wherein in S3, constructing a graph by using the prior knowledge comprises steps as follows:
1) carrying out feature mapping on the data collected by the SCADA system, wherein related features corresponding to generator components of the wind turbine generator system reflect respective operation conditions of different components; and
2) classifying the SCADA data into environment information, and internal information and output variable information of the wind turbine generator system according to the prior knowledge, wherein these three categories of information has relations that the environment information influences the internal information of the wind turbine generator system, and the internal information influences the output variable information of the wind turbine generator system.

4. The explainable method for monitoring a state of a generator of a wind turbine generator system on the basis of a spatio-temporal graph according to claim 1, wherein in S4, a prediction process of each node feature value is as follows:
the spatio-temporal information fused graph neural network comprises a graph attention network, a global and local attention embedding layer, a long short-term memory (LSTM) network and a linear regression layer;
the graph attention network transfers and updates node information Xᵢ∈R^{N×F} in directed spatio-temporal graph data Gi at an ith moment by using adjacent matrix A∈R^{N×N} of a topological relation of the prior knowledge, such that each node effectively obtains space information in the data; and
in a node set, vᵤ∈V serve as a center node and has node feature xᵤ⊂Xᵢ, Nᵤ is an adjacent node set that transmits information to vᵤ, vᵣ∈Nᵤ is one of the nodes in the set and has node feature xᵣ⊂Xᵢ, and a graph attention network process is divided into two steps as follows:
1) computing a normalized attention coefficient between the nodes by means of a graph attention mechanism, wherein a normalized attention coefficient of transmission from node vᵣ to center node vᵤ is as follows:
$${α}_{ur} = \frac{exp ( L e a k R e L U ( {a}^{T} \cdot [ {W}_{{x}_{u}} \vert \vert {W}_{{x}_{r}} ] ) )}{{\sum }_{k ∈ {N}_{u}} exp ( L e a k R e L U ( {a}^{T} \cdot [ {W}_{{x}_{u}} \vert \vert {W}_{{x}_{k}} ] ) )} , \qquad ( 2 )$$
wherein
a^{T} is a learnable neural network parameter matrix, ∥ represents a matrix splicing operation, LeakReLU( ) is a nonlinear activation function, Wₓ_{ᵤ}, Wₓ_{ᵣ} and Wₓ_{ₖ} respectively represent dimensionality transformation learnable matrices of node vᵤ, node vᵣ and node vₖ, and αᵤᵣ is a normalized attention coefficient between node vᵤ and node vᵣ;
2) transmitting a graph representation network of the node features by means of a multi-head attention mechanism, splicing all node features in a single directed graph through the matrix splicing operation, and obtaining a full-graph feature after integration of space information of all the nodes:
$${P}_{i} = {{\vert \vert}^{N}}_{n = 1} \frac{1}{M} ReLU ( {\sum }_{m = 1}^{M} {\sum }_{k ∈ {N}_{u}} {α}_{uk}^{m} {W}_{{x}_{k}} ) , \qquad ( 3 )$$
wherein
Pᵢ is the full-graph feature having the space information and processed by the graph attention network, αᵤₖ represents a normalized attention coefficient between nodes vᵤ and vₖ, and M is a number of attention heads;
3) carrying out spatio-temporal feature fusion on full-graph feature Pᵢ of the single directed graph by the global and local attention embedding layer and the long short-term memory (LSTM) network by using time sequence information in a graph sequence; wherein
the global and local attention embedding layer is expressed as follows:
$${β}_{i} = \frac{exp ( {V}^{T} tanh ( {P}_{i} ) )}{{\sum }_{i = 1}^{L} exp ( {V}^{T} tanh ( {P}_{i} ) )} , \qquad ( 4 )$$
wherein
βᵢ is a normalized local importance coefficient of directed spatio-temporal graph data at an ith moment in an entire window graph sequence, and V^{T} tan h(Pᵢ) represents a local feature at each moment in window sequence (i=1, 2, 3, . . . , L);
carrying out a splicing operation after normalized local importance coefficient βᵢ at each moment in the window sequence is obtained, forming a global feature representing entire window information, and combining the global feature with local feature Pᵢ, which is expressed as follows:
$$γ = [ {β}_{1} ‖ {β}_{2} ‖ ... ‖ {β}_{L} ] , and \qquad ( 5 )$$
$${d}_{i} = [ {P}_{i} ‖ γ ] , \qquad ( 6 )$$
wherein
γ is the global feature of the entire window information, dᵢ is a feature after global and local information fusion, and a fused feature sequence of [d₁, d₂, . . . , dᵢ, . . . , d_{L}] is output by the global and local attention embedding layer; and
inputting the output sequence into the long short-term memory network layer for spatio-temporal feature fusion, and a long short-term memory network process is expressed as follows:
$${I}_{i} = σ ( {d}_{i} {W}_{dI} + {h}_{i - 1} {W}_{hI} + {C}_{i - 1} {W}_{ci} + {b}_{i} ) , \qquad ( 7 )$$
$${F}_{i} = σ ( {d}_{i} {W}_{df} + {h}_{i - 1} {W}_{hf} + {C}_{i - 1} {W}_{cf} + {b}_{f} ) , \qquad ( 8 )$$
$${C}_{i} = {I}_{i} tanh ( {d}_{i} {W}_{dc} + {h}_{i - 1} {W}_{hc} + {b}_{c} ) + {F}_{i} {C}_{i - 1} , \qquad ( 9 )$$
$${O}_{i} = σ ( {d}_{i} {W}_{do} + {h}_{i - 1} {W}_{ho} + {C}_{i - 1} {W}_{co} + {b}_{o} ) , and \qquad ( 10 )$$
$${h}_{i} = {O}_{i} tanh ( {C}_{i} ) , \qquad ( 11 )$$
wherein
W is a learnable matrix of an input gate, a forget gate and a control gate in a long short-term memory (LSTM) network unit, b is a corresponding bias matrix, Iᵢ is an input gate feature in the long short-term memory (LSTM) network, Fᵢ is a forget gate feature, Cᵢ is a hidden state feature, Oᵢ is an output gate feature, σ represents nonlinear activation function Sigmoid( ), tan h( ) is a nonlinear activation function, and hᵢ represents spatio-temporal fusion feature output after global and local fusion sequence [d₁, d₂, . . . , dᵢ, . . . , d_{L}] passes through the long short-term memory network; and
4) predicting a feature value of each node in directed graph G at a subsequent moment by causing output spatio-temporal fusion feature hᵢ to pass through two fully connected layers.

5. The explainable method for monitoring a state of a generator of a wind turbine generator system on the basis of a spatio-temporal graph according to claim 1, wherein in S4, computing an overall feature residual of the generator of the wind turbine generator system, that is, carrying out full-graph-level state monitoring comprises: computing predicted residuals of all node features in the directed graph, and reflecting an overall operation state of the generator of the wind turbine generator system, that is, a full-graph-level state monitoring result, which is expressed by a formula as follows:
$$R M S {E}_{i}^{all} = \sqrt{\frac{1}{Q} \cdot \frac{1}{N} {\sum }_{1 - \frac{Q}{2}}^{i + \frac{Q}{2}} {\sum }_{n = 1}^{N} {( {\hat{y}}_{i}^{n} - {y}_{i}^{n} )}^{2}} , \qquad ( 12 )$$
wherein
$$R M S {E}_{i}^{all}$$
represents a residual of the full-graph-level state monitoring, Q is a size of a window for computing the residual, and
$${\hat{y}}_{i}^{n} and {y}_{i}^{n}$$
respectively represent a predicted value and an actual measured value of a feature at node vₙ of the spatio-temporal graph; and
setting a threshold for full-graph-level state monitoring result
$$R M S {E}_{i}^{all}$$
by using an exponentially weighted moving average (EWMA) control chart, which is expressed by formulas as follows:
$${E}_{i}^{all} = λ {{r}_{i}}^{all - all} + ( 1 - {λ}^{all} ) {E}_{i - 1}^{all} , and \qquad ( 13 )$$
$${Thr}^{all} ( i ) = {{μ}_{r}}^{all} + {K}^{all} {{σ}_{r}}^{all} \sqrt{\frac{{λ}^{all}}{2 - {λ}^{all}} [ 1 - {( 1 - {λ}^{all} )}^{2 i} ]} , \qquad ( 14 )$$
wherein r̅ᵢ̅^{all} is an average of predicted residuals of full-graph-level state monitoring results of an ith sample graph sequence, λ^{all}∈[0,1] represents an importance degree of a current window, μᵣ^{all} and σᵣ^{all} respectively represent a standard deviation and an average of full-graph-level state monitoring residual
$$R M S {E}_{i}^{all} ,$$
Kall is a coefficient related to an upper control limit (UCL) of the exponentially weighted moving average (EWMA) control chart, and when a predicted residual of the full-graph-level state monitoring continuously exceeds the upper control limit for 3 times, it is determined that the operation state of the generator of the wind turbine generator system is abnormal.

6. The explainable method for monitoring a state of a generator of a wind turbine generator system on the basis of a spatio-temporal graph according to claim 1, wherein in S4, a process of computing a residual of each node feature, that is, carrying out node-level state monitoring, constructing node-level abnormal information, and determining whether a fault occurs according to whether a transmission relation exits in chronological order is as follows:
1) computing a predicted residual of each node feature in the directed graph, and reflecting an operation state of a related feature of the generator of the wind turbine generator system, that is, a node-level state monitoring result, which is expressed by a formula as follows:
$$R M S {E}_{i}^{n} = \sqrt{\frac{1}{Q} {\sum }_{i - \frac{Q}{2}}^{i + \frac{Q}{2}} {( {\hat{y}}_{i}^{n} - {y}_{i}^{n} )}^{2}} , \qquad ( 15 )$$
wherein
$$R M S {E}_{i}^{n}$$
represents a residual of node-level state monitoring of node vₙ, Q is a size of a window for computing the residual, and
$${\hat{y}}_{i}^{n} and {y}_{i}^{n}$$
respectively represent a predicted value and an actual measured value of a feature at node vₙ of the spatio-temporal graph;
2) setting a threshold for residual
$$R M S {E}_{i}^{n}$$
of the node-level state monitoring through an exponentially weighted moving average (EWMA) control chart method as follows:
$${E}_{i}^{n} = λ {{r}_{i}}^{n - n} + ( 1 - {λ}^{n} ) {E}_{i - 1}^{n} , and \qquad ( 16 )$$
$${Thr}^{n} ( i ) = {{μ}_{r}}^{n} + {K}^{n} {{σ}_{r}}^{n} \sqrt{\frac{{λ}^{n}}{2 - {λ}^{n}} [ 1 - {( 1 - {λ}^{n} )}^{2 i} ]} , \qquad ( 17 )$$
and
obtaining a state monitoring threshold of each node, and reflecting, in a case that predicted residual
$$R M S {E}_{i}^{n}$$
of an nth node exceeds Thrⁿ(i) for 3 continuous times, that the generator component of the wind turbine generator system mapped by the node is abnormal; and
3) determining, in combination with a space structure of directed graph data Gᵢ constructed by the prior knowledge and a node state monitoring result, whether a fault occurs by determining whether a transmission relation exists in chronological order comprises: regarding, when a node has an abnormal condition, the node as a potential abnormal node, transmitting information to nodes adjacent to the node in directed graph data Gᵢ, making a sequence abnormal, and so on; and indicting, in cases that the adjacent nodes of the directed graph successively have node-level abnormal conditions in a subsequent time period, and a complete fault information transmission chain is formed, that in the abnormal condition, a fault actually occurs on the generator.
